(19) United States
(12) Patent Application Publication
(10) Pub. No.: US 2025/0331293 A1
(43) Pub. Date: Oct. 23, 2025

(54) SEMICONDUCTOR DEVICE

(71) Applicant: Samsung Electronics Co., Ltd., Suwon-si (KR)

(72) Inventors: Beomjin KIM, Suwon-si (KR); Seungseok HA, Suwon-si (KR); Youngwoo KIM, Suwon-si (KR); Junsoo KIM, Suwon-si (KR); Yuji MOON, Suwon-si (KR); Kyoungwoo LEE, Suwon-si (KR); Minseung LEE, Suwon-si (KR); Shinkyu CHOI, Suwon-si (KR); Junsun HWANG, Suwon-si (KR)

(73) Assignee: Samsung Electronics Co., Ltd., Suwon-si (KR)

(21) Appl. No.: 18/968,075

(22) Filed: Dec. 4, 2024

(30) Foreign Application Priority Data
Apr. 18, 2024 (KR) 10-2024-0052113

(51) Int. Cl. H10D 84/83; H10D 84/01

(52) U.S. Cl. CPC H10D 84/832; H10D 84/0128; H10D 84/013; H10D 84/0149; H10D 84/0151

(57) ABSTRACT

A semiconductor device includes a first transistor including a first gate electrode, a first gate dielectric layer, a first source/drain region, a second source/drain region, and a first channel region, a second transistor at a same level as the first transistor, the second transistor including a second gate electrode, a second gate dielectric layer, a third source/drain region, a fourth source/drain region, and a second channel region, a first source/drain backside contact structure below the first source/drain region and connected to the first source/drain region, a conductive connection pattern including at least a portion that is at a same level as the first and second gate electrodes, a backside connection pattern connected to the conductive connection pattern, a frontside connection pattern connected to the conductive connection pattern, and a first frontside contact plug on the second transistor and connected to the second transistor.

### CROSS-REFERENCE TO RELATED APPLICATION(S)

This application claims benefit of priority to Korean Patent Application No. 10-2024-0052113 filed on Apr. 18, 2024 in the Korean Intellectual Property Office, the disclosure of which is incorporated herein by reference in its entirety.

### BACKGROUND

The present inventive concepts relate to semiconductor devices.

As demand for implementation of higher performance, higher speed, and/or multi-functionalization of semiconductor devices increases, a degree of integration of semiconductor devices has been increasing. In accordance with the trend for a higher degree of integration of semiconductor devices, semiconductor devices having a backside power delivery network (BSPDN) structure, in which a power rail is disposed on a back side of a wafer, have been developed.

### SUMMARY

Some example embodiments of the present inventive concepts provide semiconductor devices having improved reliability and electrical properties.

According to an example embodiment of the present inventive concepts, a semiconductor device includes a first transistor including a first gate electrode, a first gate dielectric layer, a first source/drain region, a second source/drain region, and a first channel region, a second transistor at a same level as the first transistor, the second transistor including a second gate electrode, a second gate dielectric layer, a third source/drain region, a fourth source/drain region, and a second channel region, a first source/drain backside contact structure below the first source/drain region and connected to the first source/drain region, a conductive connection pattern having at least a portion that is at a same level as the first and second gate electrodes, a backside connection pattern below the conductive connection pattern, the backside connection pattern connected to the conductive connection pattern, a frontside connection pattern on the conductive connection pattern, the frontside connection pattern connected to the conductive connection pattern, a first frontside contact plug on the second transistor, the first frontside contact plug connected to the second transistor, and a first frontside interconnection structure on the frontside connection pattern and the first frontside contact plug, the first frontside interconnection structure electrically connecting the frontside connection pattern and the first frontside contact plug to each other. The first channel region may include first channel layers spaced apart from each other in a vertical direction. The second channel region may include second channel layers spaced apart from each other in the vertical direction. The first channel layers may be between the first source/drain region and the second source/drain region. The second channel layers may be between the third source/drain region and the fourth source/drain region.

According to an example embodiments of the present inventive concepts, a semiconductor device includes a backside insulating layer, a gate structure on the backside insulating layer, the gate structure including a gate electrode extending in a first direction, a first source/drain region and a second source/drain region on opposite sides of the gate structure, the first source/drain region and the second source/drain region spaced apart from each other, a channel region between the first and second source/drain regions, the channel region overlapping at least a portion of the gate electrode in a vertical direction, a conductive connection pattern extending in the first direction, the conductive connection pattern including at least a portion that is at a same level the same as the gate electrode, the conductive connection pattern, a frontside connection pattern on the conductive connection pattern, the frontside connection pattern being in contact with the conductive connection pattern, a backside connection pattern below the conductive connection pattern, the backside connection pattern being in contact with the conductive connection pattern, a first frontside contact plug on the gate electrode, the first frontside contact plug connected to the gate electrode, a first frontside interconnection structure on the frontside connection pattern and the first frontside contact plug, the first frontside interconnection structure connecting the frontside connection pattern and the first frontside contact plug to each other, a first backside contact structure below the first source/drain region, the first backside contact structure connected to the first source/drain region, and a first source/drain frontside contact plug on the second source/drain region, the first source/drain frontside contact plug connected to the second source/drain region.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a plan view of a semiconductor device according to an example embodiment of the present inventive concepts;

FIG. 2A is a cross-sectional view of the semiconductor device in FIG. 1, taken along line I-I′, and FIG. 2B is a cross-sectional view of the semiconductor device in FIG. 1, taken along line II-II′;

FIG. 3 is a plan view of a semiconductor device according to an example embodiment of the present inventive concepts;

FIG. 4A is a cross-sectional view of the semiconductor device in FIG. 3, taken along line I-I′, and FIG. 4B is a cross-sectional view of the semiconductor device in FIG. 3, taken along line II-II′;

FIG. 5 is a plan view of a semiconductor device according to an example embodiment of the present inventive concepts;

FIG. 6 is a cross-sectional view of the semiconductor device in FIG. 5, taken along line II-II′;

FIG. 7 is a cross-sectional view of a semiconductor device according to an example embodiment of the present inventive concepts, taken along line II-II′;

FIG. 8 is a cross-sectional view of a semiconductor device according to an example embodiment of the present inventive concepts, taken along line I-I′;

FIG. 9 is a cross-sectional view of a semiconductor device according to an example embodiment of the present inventive concepts, taken along line I-I′;

FIG. 10 is a cross-sectional view of a semiconductor device according to an example embodiment of the present inventive concepts, taken along line I-I′;

FIG. 11 is a cross-sectional view of a semiconductor device according to an example embodiment of the present inventive concepts, taken along line I-I′; and

FIGS. 12 to 23B are cross-sectional views of sequential processes of a method of manufacturing a semiconductor device according to an example embodiment.

### DETAILED DESCRIPTION

Hereinafter, preferred example embodiments of the present inventive concepts will be described with reference to the accompanying drawings. Hereinafter, terms such as “top,” “upper portion,” “upper surface,” “above,” “bottom,” “lower portion,” “lower surface,” “below,” and “side surface” may be understood as being referred to, based on the drawings except for being denoted by reference numerals.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

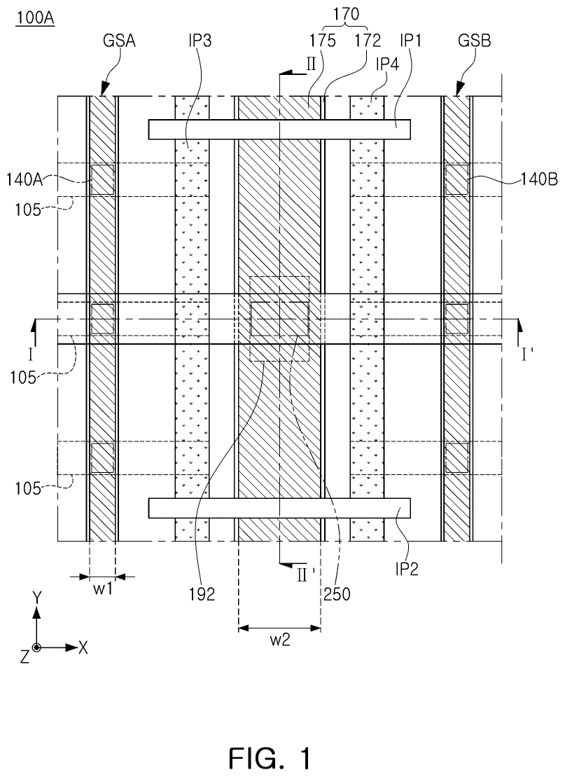

FIG. 1 is a plan view of a semiconductor device 100A according to an example embodiment of the present inventive concepts.

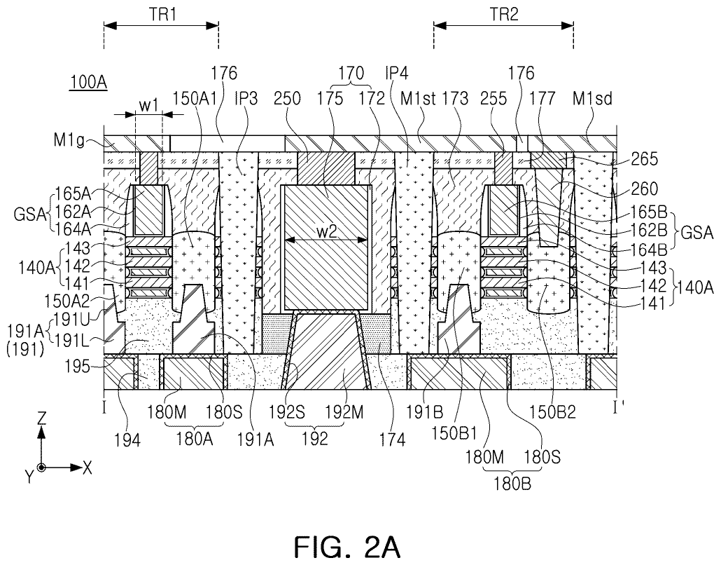

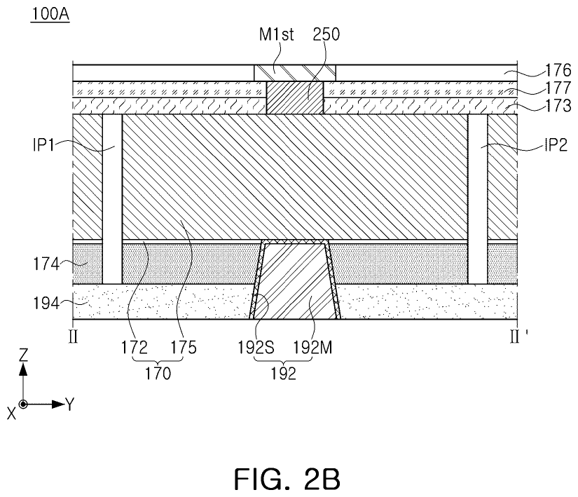

FIG. 2A is a cross-sectional view of the semiconductor device 100A in FIG. 1, taken along line I-I′, and FIG. 2B is a cross-sectional view of the semiconductor device 100A in FIG. 1, taken along line II-II′. To aid understanding, only some components of the semiconductor device 100A are illustrated in FIG. 1.

Referring to FIGS. 1, 2A, and 2B, the semiconductor device 100A according to an example embodiment may include first and second transistors TR1 and TR2 spaced apart from each other. The semiconductor device 100A may further include a source/drain backside contact structure 191, a connection structure 170, a frontside connection pattern 250, a backside connection pattern 192, a first frontside contact plug (interchangeably, referred to as a gate contact) 255, a first frontside interconnection structure M1, and a backside interconnection structure 180.

The first transistor TR1 may include a first gate electrode 165A, a first gate dielectric layer 162A, a first source/drain region 150A1, a second source/drain region 150A2, and a first channel region 140A. The second transistor TR2 may be disposed on a level the same as that of the first transistor TR1, and may include a second gate electrode 165B, a second gate dielectric layer 162B, and a third source/drain region 150B1, a fourth source/drain region 150B2, and a second channel region 140B, and the first transistor TR1 may be disposed to be spaced apart from the second transistor TR2 in a second direction (e.g., an X-axis direction). A connection structure 170, a frontside connection pattern 250, and a backside connection pattern 192 may be disposed between the first transistor TR1 and the second transistor TR2.

The semiconductor device 100A may further include a backside insulating layer 194.

The first and second transistors TR1 and TR2 may be disposed on the backside insulating layer 194. The backside insulating layer 194 may have an upper surface extending in a first direction (e.g., a Y-axis direction) and a second direction (e.g., an X-axis direction). The backside insulating layer 194 may be a layer formed using an additional process after a semiconductor substrate, formed of or include a semiconductor material, is removed during a manufacturing process, or may be a layer formed by oxidizing the semiconductor substrate. The backside insulating layer 194 may be in the form of a substrate insulating layer formed of an insulating material, and may include, for example, oxide, nitride, or a combination thereof. In some example embodiments, the backside insulating layer 194 may include a plurality of insulating layers including different materials.

A lower pattern 195, extending in the second direction (e.g., an X-axis direction), may be disposed on the backside insulating layer 194. The lower pattern 195 may have a fin structure protruding in a third direction (e.g., a Z-axis direction). In some example embodiments, the lower pattern 195 may have a cross-section having a downwardly increasing width. The lower pattern 195 may include various insulating materials such as oxide, nitride, or oxynitride. In an example, in the lower pattern 195, an upper region may include a semiconductor material, and a lower region may include an insulating material. The lower pattern 195 may overlap channel regions 140 in a vertical direction (e.g., a Z-axis direction), but the present inventive concepts are not limited thereto.

The gate structures GS may include a first gate structure GSA and a second gate structure GSB. The first gate structure GSA may be disposed on the lower pattern 195 to extend in the first direction (e.g., a Y-axis direction). The first gate structure GSA may include a first gate dielectric layer 162A, a first gate spacer layer 164A, and a first gate electrode 165A. In some example embodiments, the first gate structures GSA may further include a capping layer on an upper surface of the first gate electrode 165A. Alternatively, a portion of a first interlayer insulating layer 173 on the first gate structures GSA may be referred to as a gate capping layer. A width of the first gate structure GSA in the second direction (e.g., an X-axis direction) may be referred to as a first width w1. The second direction may be a direction, intersecting the first direction in which the first gate structure GSA extends.

The first gate dielectric layer 162A may be disposed between the lower pattern 195 and the first gate electrode 165A, and between the first channel region 140A and the first gate electrode 165A, and may be disposed to cover at least a portion of surfaces of the first gate electrode 165A. For example, the first gate dielectric layer 162A may be disposed to surround surfaces of the first gate electrode 165A, excluding an uppermost surface of the first gate electrode 165A. The first gate dielectric layer 162A may extend to a space between the first gate electrode 165A and the first gate spacer layers 164A, but the present inventive concepts are not limited thereto. The first gate dielectric layer 162A may include oxide, nitride, or a high-K material. The high-K material may refer to a dielectric material having a dielectric constant, which is higher than that of a silicon oxide film (SiO₂). The high-material may include, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). In some example embodiments, the first gate dielectric layer 162A may have a multilayer structure.

The first gate electrode 165A may include a conductive material, for example, a metal nitride such as titanium nitride (TiN), tantalum nitride (TaN), or tungsten nitride (WN), and/or a metal material such as aluminum (Al), tungsten (W), or molybdenum (Mo) or a semiconductor material such as doped polysilicon. Depending on example embodiments, the first gate electrode 165A may have a multilayer structure.

The first gate spacer layers 164A may be disposed on opposite side surfaces of the first gate electrode 165A, on the channel region 140. The first gate spacer layers 164A may insulate the source/drain regions 150 and the first gate electrode 165A from each other. Depending on example embodiments, upper ends of the first gate spacer layers 164A may have a shape changed in various manners, and the first gate spacer layers 164A may have a multilayer structure. The first gate spacer layers 164A may be formed of a low-K material, and may include, for example, at least one of SiO, SiN, SiCN, SiOC, SiON, or SiOCN.

The second gate structure GSB may include a second gate dielectric layer 162B, a second gate spacer layer 164B, and a second gate electrode 165B. The second gate structure GSB may have features the same as or similar to those of the first gate structure GSA, and descriptions of the second gate structure GSB may be replaced with the above descriptions of the first gate structure GSA. The second gate structure GSB may be spaced apart from the first gate structure GSA in the second direction (e.g., an X-axis direction), and a connection structure 170, a frontside connection pattern 250, and a backside connection pattern 192 may be disposed between the first and second gate structures GSA and GSB.

The channel regions 140 may include a first channel region 140A disposed on the first transistor TR1, and a second channel region 140B disposed on the second transistor TR2. The first channel region 140A may be disposed on the lower pattern 195 in regions in which the lower pattern 195 intersects the first gate structure GSA. The first channel region 140A may include two or more first channel layers 141, 142, and 143 disposed to be spaced apart from each other in the third direction (e.g., a Z-axis direction). The first channel region 140A may be disposed between the first source/drain region 150A1 and the second source/drain region 150A2, and the first channel region 140A may be connected to the first and second source/drain regions 150A1 and 150A2. The first channel region 140A may have a width equal to or less than that of the lower pattern 195 in the second direction (e.g., a X-axis direction), and may have a width equal to or similar to that of the first gate structure GSA in the second direction (e.g., an X-axis direction). In a cross-section in the first direction, among the plurality of first channel layers 141, 142, and 143, a lower channel layer 141 may have a width equal to or greater than that of an upper channel layer 143. In some example embodiments, the first channel region 140A may have a reduced width, as compared to the first gate structure GSA, such that side surfaces of the first channel region 140A may be positioned below the first gate structure GSA in the second direction.

The first channel region 140A may be formed of a semiconductor material, and may include, for example, at least one of silicon (Si), silicon germanium (SiGe), or germanium (Ge). In example embodiments, the number and shape of channel layers, included in a single channel structure, may be changed in various manners.

In the semiconductor device 100A, the first gate electrode 165A may be disposed between the lower pattern 195 and the first channel region 140A, between the plurality of first channel layers 141, 142, and 143 of the first channel region 140A, and on the first channel region 140A. Accordingly, the semiconductor device 100A may include a transistor having a multi bridge channel FET (MBCFET™) structure and a gate-all-around type field effect transistor. However, in some example embodiments, the semiconductor device 100A may not include the plurality of first channel layers 141, 142, and 143, and may have, for example, a FinFET structure.

The second channel region 140B may include second channel layers spaced apart from each other in the vertical direction. The second channel region 140B may be disposed between the third source/drain region 150B1 and the fourth source/drain region 150B2, and the second channel region 140B may be electrically connected to the third and fourth source/drain regions 150B1 and 150B2. The second channel region 140B may have features the same as or similar to those of the first channel region 140A, and descriptions of the second channel region 140B may be replaced with the above descriptions of the first channel region 140A. The second channel region 140B may be spaced apart from the first channel region 140A in the second direction (e.g., an X-axis direction), and a connection structure 170, a frontside connection pattern 250, and a backside connection pattern 192 may be disposed between the first and second channel regions 140A and 140B.

The source/drain regions 150 may include first and second source/drain regions 150A1 and 150A2, and third and fourth source/drain regions 150B1 and 150B2. The first and second source/drain regions 150A1 and 150A2 may be disposed on opposite sides of the first gate structure GSA, respectively, to be in contact with the first channel region 140A. The first source/drain regions 150A1 may be disposed in regions in each of which an upper portion of the lower pattern 195 is partially recessed. The source/drain regions 150 may be referred to differently depending on a region in which the source/drain regions 150 are disposed. As illustrated in FIG. 2A, the first and second source/drain regions 150A1 and 150A2 may be electrically connected to a first source/drain backside contact structure 191A, which is in contact with lower surfaces of the first and second source/drain regions 150A1 and 150A2. The third source/drain region 150B1 may be electrically connected to a second source/drain backside contact structure 191B, which is in contact with a lower surface of the third source/drain region 150B1, and the fourth source/drain region 150B2 may be electrically connected to a first source/drain frontside contact plug 260, which is in contact with an upper surface of the fourth source/drain region 150B2.

Upper surfaces of the source/drain regions 150 may be positioned on a level the same as or similar to that of lower surfaces of the gate structures GS on the channel regions 140. However, the level of the upper surfaces of the source/drain regions 150 may be changed in various manners in example embodiments. The source/drain regions 150 may include a semiconductor material, for example, silicon (Si) and/or germanium (Ge), and may further include impurities.

The semiconductor device 100A may further include a connection structure 170 and an intermediate insulating layer 174.

The connection structure 170 may extend in the first direction (e.g., a Y-axis direction) to be parallel to the gate structures GS, on the backside insulating layer 194. At least a portion of the connection structure 170 may be positioned on a level the same as that of at least a portion of the gate structures GS. The connection structure 170 may include a conductive connection pattern 175 and an insulating liner 172 surrounding the conductive connection pattern 175. At least a portion of the conductive connection pattern 175 may be disposed on a level the same as that of the gate electrode 165. The conductive connection pattern 175 may include a material the same as that of the gate electrode 165, and may have features the same as or similar to those of the first gate electrode 165A. Descriptions of the conductive connection pattern 175 may be replaced with the above descriptions of the first gate electrode 165A. The insulating liner 172 may include a material the same as that of the first gate dielectric layer 162A, and may have features the same as or similar to those of the first gate dielectric layer 162A. Descriptions of the insulating liner 172 may be replaced with the above descriptions of the first gate dielectric layer 162A.

A distance between an upper surface and a lower surface of the conductive connection pattern 175 may be greater than a distance between an upper surface and a lower surface of the first gate electrode 165A, but the present inventive concepts are not limited thereto. The lower surface of the first gate electrode 165A may be positioned on a level, higher than that of the lower surface of the conductive connection pattern 175. The upper surface of the conductive connection pattern 175 may be disposed on a level, higher than that of the uppermost first channel layer 143, among the first channel layers, and the lower surface of the conductive connection pattern 175 may be disposed on a level, lower than that of the lowermost first channel layer 141, among the first channel layers.

A width of the conductive connection pattern 175 in the second direction (e.g., an X-axis direction) may be referred to as a second width w2. The second width w2 of the conductive connection pattern 175 may be greater than the first width w1 of each of the first and second gate electrodes 165A and 165B, but the present inventive concepts are not limited thereto. The semiconductor device 100A according to the present example embodiment may include the conductive connection pattern 175 having a width greater than that of the gate electrode, thereby providing a position on which a contact structure extending from a back side of a semiconductor device is provided while easily achieving electrical connection to the contact structure.

The intermediate insulating layer 174 may be disposed on the backside insulating layer 194, and may be disposed below the connection structure 170. The intermediate insulating layer 174 may include at least one of oxide, nitride, oxynitride, or a low-K material. In an example embodiment, the intermediate insulating layer 174 may include oxide. The intermediate insulating layer 174 may be disposed to surround at least a portion of the backside connection pattern 192. The intermediate insulating layer 174 may be disposed on a level the same as or lower than that of the connection structure 170, and may provide an aligned position, such that the backside connection pattern 192 may be in contact with the connection structure 170. At least a portion of an upper surface of the intermediate insulating layer 174 may be in contact with at least a portion of the insulating liner 172. The upper surface of the intermediate insulating layer 174 may be positioned on a level the same as or similar to that of a lowermost end of the source/drain regions 150, disposed to be spaced apart from each other in the first direction, but the present inventive concepts are not limited thereto. A lower surface of the intermediate insulating layer 174 may be positioned on a level the same as or similar to that of a lower surface of each of a third and fourth insulating separation patterns IP3, IP4 and the source/drain backside contact structure 191, disposed to be spaced apart from each other in the first direction, but the present inventive concepts are not limited thereto.

The semiconductor device 100A may further include a backside connection pattern 192, source/drain backside contact structures 191, and a backside interconnection structure 180.

The source/drain backside contact structures 191 may be disposed on the first and second transistors TR1 and TR2. For example, the source/drain backside contact structures 191A may be disposed below the first source/drain region 150A1. The source/drain backside contact structure 191A may pass through a lower pattern 195 to be electrically connected to the source/drain region 150A1. The source/drain backside contact structure 191 may have an inclined side surface such that a portion of an upper region 191U decreases in width toward an upper surface of the backside insulating layer 194 due to an aspect ratio thereof, and a lower region 191L may have a width that is not changed depending on a level thereof, and may have a certain shape, but the present inventive concepts are not limited thereto. Lower ends of the source/drain backside contact structure 191 may be positioned on a level, lower than that of lower ends of the first source/drain region 150A1. The source/drain backside contact structure 191 may be disposed to partially recess the first source/drain region 150A1 and to be in contact with a portion of surfaces including a lower surface of the first source/drain region 150A1. In example embodiments, a form in which the source/drain backside contact structure 191 is connected to the source/drain regions 150 may be changed in various manners.

The source/drain backside contact structure 191 may include first source/drain backside contact structures 191A in contact with and electrically connected to the first and second source/drain regions 150A1 and 150A2 of the first transistor TR1, respectively, and a second source/drain backside contact structure 191B in contact with and electrically connected to the third source/drain region 150B1 of the second transistor TR2

The first source/drain backside contact structures 191A may have upper ends extending into the first and second source/drain regions 150A1 and 150A2 such that the upper ends is disposed on a level higher than that of lower ends of the first and second source/drain regions 150A1 and 150A2. The second source/drain backside contact structure 191B may have an upper end extending into the third source/drain region 150B1 such that the upper end is disposed on a level higher than that of a lower end of the third source/drain region 150B1.

The source/drain backside contact structure 191 may include a first contact barrier layer (not illustrated), forming side and lower surfaces thereof, and a first contact conductive layer on the first contact barrier layer. For example, the first contact barrier layer may include a metal nitride such as titanium nitride (TiN), tantalum nitride (TaN), or tungsten nitride (WN). For example, the first contact conductive layer may include a metal material such as aluminum (Al), tungsten (W), or molybdenum (Mo). In example embodiments, the number and arrangement of conductive layers, included in the source/drain backside contact structure 191, may be changed in various manners.

The source/drain backside contact structure 191 may be in contact with the lower surface of the first source/drain region 150A1, and may serve to apply a power voltage to source/drain regions of a power transistor in a semiconductor device from the backside interconnection structure 180.

The backside connection pattern 192 may be disposed below the connection structure 170. The backside connection pattern 192 may be disposed below the conductive connection pattern 175, and may be electrically connected to the conductive connection pattern 175. The backside connection pattern 192 may have an inclined side surface such that a width thereof decreases toward the connection structure 170. The backside connection pattern 192 may include a backside contact barrier layer 192S, forming side and upper surfaces thereof, and a backside contact conductive layer 192M on the backside contact barrier layer 192S. The backside contact barrier layer 192S may include a metal nitride, such as titanium nitride (TiN), tantalum nitride (TaN), or tungsten nitride (WN). The backside contact conductive layer 192M may include a metal material such as copper (Cu), aluminum (Al), tungsten (W), or molybdenum (Mo). In example embodiments, the number and arrangement of conductive layers, included in the backside connection pattern 192, may be changed in various manners. The backside contact barrier layer 192S may be in contact with the conductive connection pattern 175. For example, the backside contact barrier layer 192S may be in contact with the lower surface of the conductive connection pattern 175, and the insulating liner 172 may be disposed to surround the backside contact barrier layer 192S. The backside connection pattern 192 may provide an electrical path for signal transmission from the backside interconnection structure 180.

The backside interconnection structure 180 may include a backside barrier layer 180S and a backside electrode layer 180M disposed on the backside barrier layer 180S. The backside interconnection structure 180 may be in contact with a lower portion of the source/drain backside contact structure 191, and may be electrically connected to the first source/drain backside contact structure 191, through the source/drain backside contact structure 191. The first backside interconnection structure 180 may be disposed on a lower surface of the backside insulating layer 194. The backside interconnection structure 180, together with the source/drain backside contact structure 191, may form a backside power delivery network (BSPDN) applying a power or ground voltage, and may also be referred to as a backside power rail or buried power rail. For example, the backside interconnection structure 180 may be a buried interconnection line extending in one direction, for example, a Y-direction, below the source/drain backside contact structure 191, but the form of the backside interconnection structure 180 is not limited thereto. For example, in some example embodiments, the backside interconnection structure 180 may include a via region and/or a line region. The backside interconnection structure 180 may include first backside interconnection structures 180A in contact with the first source/drain backside contact structures 191A, and a second backside interconnection structure 180B in contact with the second source/drain backside contact structure 191B. The first backside interconnection structures 180A may be in contact with the first source/drain backside contact structures 191A, and may be electrically connected to the first transistor TR1 through the first source/drain backside contact structures 191A. The second backside interconnection structure 180B may be in contact with the second source/drain backside contact structure 191B, and may be electrically connected to the second transistor TR2 through the second source/drain backside contact structure 191B. In FIG. 2A illustrates that the backside interconnection structure 180 has a single interconnection layer, but the number of layers is not limited thereto. The backside interconnection structure 180 may include interconnection lines of a plurality of layers stacked in the vertical direction and electrically connected to each other.

The backside interconnection structure 180 may include a conductive material, for example, at least one of tungsten (W), copper (Cu), aluminum (Al), cobalt (Co), ruthenium (Ru), titanium (Ti), or molybdenum (Mo).

The semiconductor device 100A may further include a frontside connection pattern 250, a first source/drain frontside contact plug 260, a first source/drain frontside contact via 265, and a first frontside interconnection structure M1.

The frontside connection pattern 250 may be disposed on the connection structure 170. The frontside connection pattern 250 may be disposed on the conductive connection pattern 175, and may be electrically connected to the conductive connection pattern 175. The frontside connection pattern 250 may have features the same as or similar to those of the backside connection pattern 192, and descriptions of the frontside connection pattern 250 may be partially replaced by the above descriptions of the backside connection pattern 192. The frontside connection pattern 250 may pass through a portion of the first interlayer insulating layer 173, and may be in contact with an upper surface of the connection structure 170. The frontside connection pattern 250 may be electrically connected to the connection structure 170, and may provide an electrical path for transmission of an operation signal from the backside interconnection structure 180. An upper surface of the first source/drain backside contact structure 191 may be at a higher level a lower surface of the conductive connection pattern 250, and a lower surface of the first source/drain backside contact structure 191 is at a lower level a lower surface of the conductive connection pattern 250. In the semiconductor device 100A according to the present example embodiment, a direct electrical path, passing through the backside connection pattern 192, the connection structure 170, and the frontside connection pattern 250, may be used, thereby resolving various resistance issues that may occur due to a lengthened electrical path.

On the second transistor TR2, the first source/drain frontside contact plug 260 may be disposed on the fourth source/drain region 150B2. The first source/drain frontside contact plug 260 may pass through the first interlayer insulating layer 173 to be electrically connected to the fourth source/drain region 150B2. The first source/drain frontside contact plug 260 may have an inclined side surface such that a width thereof decreases toward an upper surface of the backside insulating layer 194 due to an aspect ratio thereof, but the present inventive concepts are not limited thereto. A lower end of the first source/drain frontside contact plug 260 may be positioned on a level higher than that of lower ends of the fourth source/drain region 150B2. The first source/drain frontside contact plug 260 may be disposed to partially recess the fourth source/drain regions 150B2 and to be in contact with a portion of surfaces including upper surfaces of the fourth source/drain regions 150B2. In example embodiments, a form in which the first source/drain frontside contact plug 260 is connected to the fourth source/drain regions 150B2 may be changed in various manners.

The first source/drain frontside contact plug 260 may have features the same as or similar to those of the source/drain backside contact structure 191, and descriptions of the first source/drain frontside contact plug 260 may be partially replaced with the above descriptions of the source/drain backside contact structure 191.

The first source/drain frontside contact plug 260 may be in contact with the upper surfaces of the fourth source/drain regions 150B2, and may serve to transmit, from the first frontside interconnection structure M1, an input/output signal to source/drain regions of a logic transistor in a semiconductor device.

The first source/drain frontside contact via 265 may be disposed on the first source/drain frontside contact plug 260, and may be in contact with the first frontside interconnection structure M1. The first source/drain frontside contact via 265 may include a material the same as that of the first source/drain frontside contact plug 260. For example, the first source/drain frontside contact via 265 may include a conductive metal material the same as that of the first source/drain frontside contact plug 260, and may serve as an electrical path for transmitting, from the first source/drain frontside contact plug 260, power to the first frontside interconnection structure M1.

The first frontside interconnection structure M1 may be disposed on the first interlayer insulating layer 173, the frontside connection pattern 250, and the first source/drain frontside contact plug 260. The first frontside interconnection structure M1 may be disposed on a level the same as that of a second interlayer insulating layer 177. The first frontside interconnection structure M1 may have a structure in which the first frontside interconnection structure M1 is divided into a plurality of portions, and the plurality of portions may be electrically connected to different contact structures. The first frontside interconnection structure M1 may include a first interconnection line M1st in contact with the frontside connection pattern 250 and the first frontside contact plug 255, a second interconnection line M1sd in contact with the first source/drain frontside contact via 265, and a third interconnection line M1g in contact with the first frontside contact plug 255. The first frontside interconnection structure M1 may have features the same as or similar to those of the backside interconnection structure 180, and descriptions of the first frontside interconnection structure M1 may be partially replaced with the above descriptions of the backside interconnection structure 180. The first frontside interconnection structure M1 may be electrically connected to the first frontside contact structure 250 and the second frontside contact structure 260, and may provide an electrical path for transmitting an operation signal. Only a single layer of the first frontside interconnection structure M1 is illustrated, but the number or form thereof is not limited thereto, and a transmission path of an electrical signal may be provided by additional interconnection lines disposed on the illustrated first frontside interconnection structure M1.

The semiconductor device 100A may further include a device isolation layer 110.

The device isolation layer 110 may fill a space between lower patterns 195, and may define the lower pattern 195 in the backside insulating layer 194. For example, the device isolation layer 110 may be formed using a shallow trench isolation (STI) process. The device isolation layer 110 may expose an upper surface of the lower pattern 195, and may partially expose an upper portion of the lower pattern 195. The device isolation layer 110 may be formed of an insulating material. The device isolation layer 110 may include, for example, oxide, nitride, or a combination thereof. In the semiconductor device 100A according to the present example embodiment, the lower pattern 195 and the device isolation layer 110 may be partially removed below the connection structure 170, but the present inventive concepts are not limited thereto. The connection structure 170 may overlap the lower pattern 195 and the channel regions 140, which is disposed on the lower pattern 195, in the third direction (e.g., a Z-axis direction).

The semiconductor device 100A may further include first to fourth insulating separation patterns IP1, IP2, IP3, and IP4.

The first and second insulating separation patterns IP1 and IP2 may extend in the second direction (e.g., an X-axis direction), on the backside insulating layer 194. The first and second insulating separation patterns IP1 and IP2 may be spaced apart from each other in the first direction (e.g., a Y-axis direction). The first and second insulating separation patterns IP1 and IP2 may intersect the connection structure 170 extending in the first direction, and the first and second insulating separation patterns IP1 and IP2 may separate the conductive connection pattern 175 into a plurality of divided portions. The conductive connection pattern 175 may be disposed between the first and second insulating separation patterns IP1 and IP2. The first and second insulating separation patterns IP1 and IP2 may include an insulating material, and may include a material formed of oxide, nitride, oxynitride, or combinations thereof. As illustrated in FIG. 1, the first and second insulating separation patterns IP1 and IP2 may not be in contact with the gate structure GS. However, depending on example embodiments, the first and second insulating separation patterns IP1 and IP2 may extend to intersect the first and second gate structures GSA and GSB, and may separate each of the first and second gate structures GSA and GSB into a plurality of divided portions.

The third and fourth insulating separation patterns IP3 and IP4 may be disposed on the backside insulating layer 194. The third insulating separation pattern IP3 may be disposed between the first transistor TR1 and the connection structure 170, and the fourth insulating separation pattern IP4 may be disposed between the second transistor TR2 and the connection structure 170. The connection structure 170 may be disposed between the third and fourth insulating separation patterns IP3 and IP4. The third and fourth insulating separation patterns IP3 and IP4 may extend in the first direction (e.g., a Y-axis direction). The third and fourth insulating separation patterns IP3 and IP4 may pass through at least a portion of the lower pattern 195, and may extend in the third direction (e.g., a Z-axis direction). Lower surfaces of each of the third and fourth insulating separation patterns IP3 and IP4 may be positioned on a level the same as that of a lower surface of the lower pattern 195 and the upper surface of the backside insulating layer 194, and may be positioned on a level the same as that of the lower surface of the intermediate insulating layer 174, but the present inventive concepts are not limited thereto. Upper surfaces of each of the third and fourth insulating separation patterns IP3 and IP4 may be disposed on a level higher than that of the upper surface of the conductive connection pattern 175, and lower surfaces of each of the third and fourth insulating separation patterns IP3 and IP4 may be disposed on a level lower than that of the lower surface of the conductive connection pattern 175, but the present inventive concepts are not limited thereto. In the second direction (e.g., an X-direction), perpendicular to the first direction, a maximum width w2 of the conductive connection pattern 175 may be greater than a width of each of the third and fourth insulating separation patterns IP3 and IP4. The third and fourth insulating separation patterns IP3 and IP4 may include an insulating material, for example, oxide, nitride, oxynitride, or combinations thereof. The third and fourth insulating separation patterns IP3 and IP4 may pass through the channel regions 140, and may serve to insulate electrical signals between the third and fourth insulating separation patterns IP3 and IP4 from each other.

The semiconductor device 100A may further include a first interlayer insulating layer 173, a second interlayer insulating layer 177, and a frontside insulating layer 176.

The first interlayer insulating layer 173 may be disposed to cover the source/drain regions 150, the gate structures GS, and the intermediate insulating layer 174. The first interlayer insulating layer 173 may be disposed to surround at least a portion of each of the connection structure 170, the first frontside contact structure 250, and the second frontside contact structure 260. The first interlayer insulating layer 173 may include at least one of oxide, nitride, or oxynitride, and may include, for example, a low-K material. Depending on example embodiments, the first interlayer insulating layer 173 may include a plurality of insulating layers.

The second interlayer insulating layer 177 may be disposed on the first interlayer insulating layer 173. The second interlayer insulating layer 177 may be disposed to surround at least a portion of each of the frontside connection pattern 250 and a gate contact 255. The second interlayer insulating layer 177 may have features the same as or similar to those of the first interlayer insulating layer 173, and thus descriptions of the frontside insulating layer 176 may be partially replaced with the above descriptions of the first interlayer insulating layer 173.

The frontside insulating layer 176 may be disposed on the second interlayer insulating layer 177. The frontside insulating layer 176 may be disposed to surround the first frontside interconnection structure M1. The frontside insulating layer 176 may have features the same as or similar to those of the first interlayer insulating layer 173, and thus descriptions of the frontside insulating layer 176 may be partially replaced with the above descriptions of the first interlayer insulating layer 173.

A second source/drain backside interconnection structure 180B and the second source/drain backside contact structure 191B may be transmission paths for applying a source/drain voltage to the third source/drain region 150B1. The fourth source/drain region 150B2 may be electrically connected to the second interconnection line M1sd through the first source/drain frontside contact plug 260 and the first source/drain frontside contact via 265.

A gate voltage, applied to the second gate electrode 165B, may be applied through the backside connection pattern 192, the conductive connection pattern 175, the frontside connection pattern 250, the first interconnection line M1st, and the first frontside contact plug 255.

In an example, the second transistor TR2 may be a power transistor, but example embodiments are not limited thereto, and may be a transistor included in a logic circuit.

In the semiconductor device 100A according to the present example embodiment, the backside connection pattern 192 in contact with backside power structures, and the connection structure 170 disposed on the backside connection pattern 192 may be used, thereby providing a shortened path of an operation signal transmitted from a back side to a frontside side. Accordingly, the semiconductor device may have improved performance. In addition, a width w2 of the connection structure 170 in the first direction (e.g., an X-direction) may be greater than a width w1 of the gate structure GS in the first direction, such that the backside connection pattern 192 may be aligned to the connection structure 170 in the vertical direction (e.g., Z-axis direction), thereby providing a path of power or an input/output signal without interruption.

In descriptions of the following example embodiments below, descriptions overlapping the above descriptions provided with reference to FIGS. 1 to 2B will be omitted.

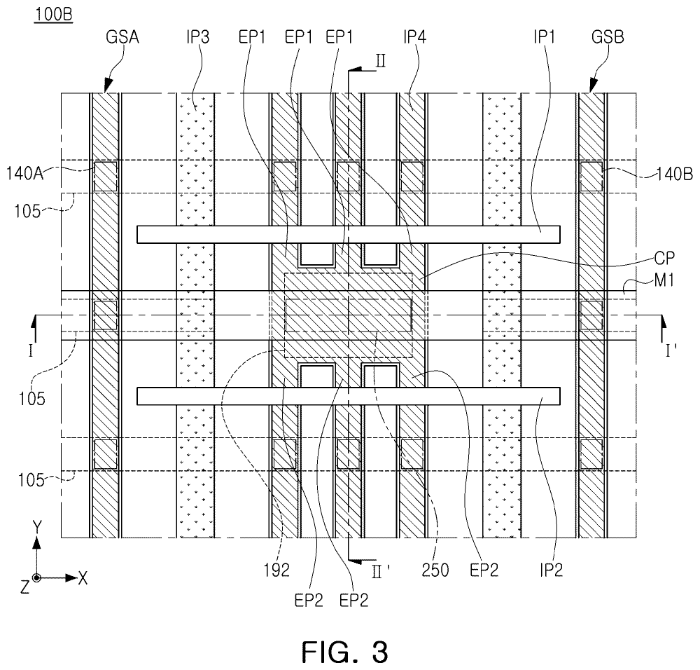

FIG. 3 is a plan view of a semiconductor device 100B according to an example embodiment of the present inventive concepts.

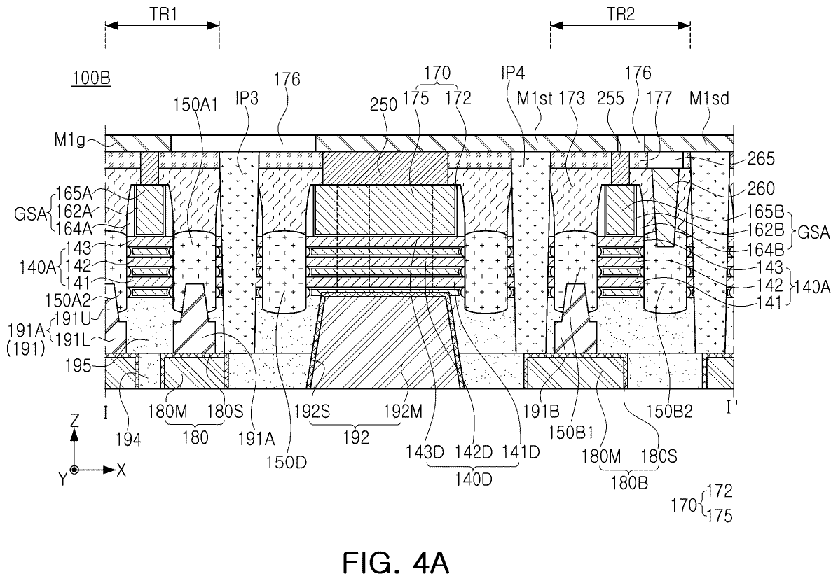

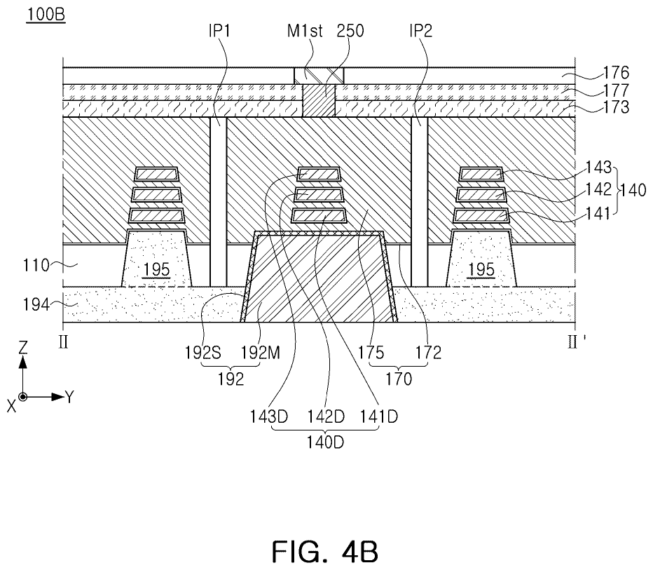

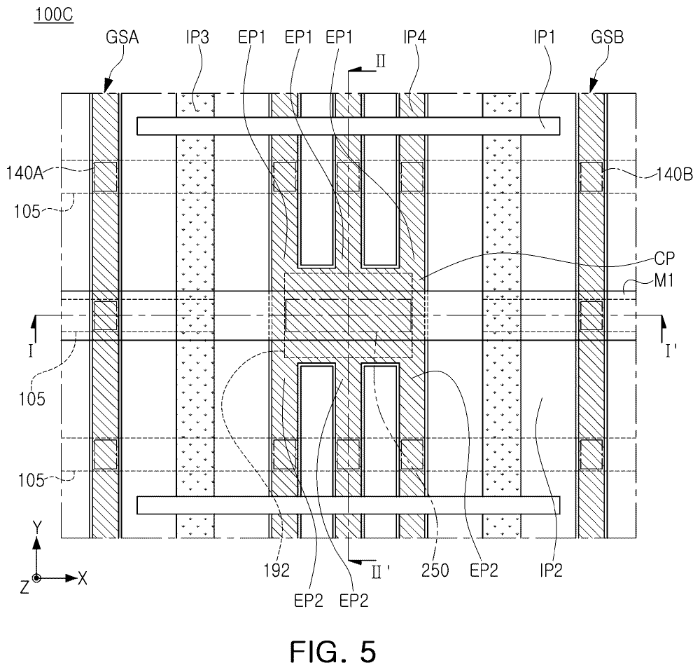

FIG. 4A is a cross-sectional view of the semiconductor device 100B in FIG. 3, taken along line I-I′, and FIG. 5B is a cross-sectional view of the semiconductor device 100B in FIG. 3, taken along line II-II′.

Referring to FIGS. 3, 4A, and 4B, the semiconductor device 100B according to an example embodiment may have features the same as or similar to those described with reference to FIGS. 1 to 2B, except that a conductive connection pattern 175 includes a first central portion CP, first extension portions EP1 extending from the first central portion CP, and second extension portions EP2 extending from the first central portion CP, the second extension portions EP2 respectively spaced apart from the first extension portions EP1 in a first direction. The conductive connection pattern 175 may include a first central portion CP, first extension portions EP1 extending from the first central portion CP in the first direction (e.g., a Y-axis direction), the first extension portions EP1 disposed between the first central portion CP and a first insulating separation pattern IP1, and second extension portions EP2 extending from the first central portion CP in a second direction, the second extension portions EP2 disposed between the first central portion CP and a second insulating separation pattern IP2. The plurality of first extension portions EP1 may be spaced apart from each other in the second direction (e.g., an X-axis direction), perpendicular to the first direction, and the second extension portions EP2 may be spaced apart from each other in the second direction. The semiconductor device 100B according to the present example embodiment may include a plurality of dummy channel layers 140D, overlapping a backside connection pattern 192 in a vertical direction (e.g., a Z-axis direction). The dummy channel layers 140D may be disposed between the first and second insulating separation patterns IP1 and IP2, and between the third and fourth insulating separation patterns IP3 and IP4. The conductive connection pattern 175 may extend in the first direction (e.g., a Y-axis direction), and may cover an upper surface, a lower surface, and a side surface of at least one of the dummy channel layers 140D. The dummy channel layers 140D may include a material the same as that of a plurality of first and second channel layers of first and second channel regions 140A and 140B, and may have features the same as or similar to those of the plurality of first and second channel layers of first and second channel regions 140A and 140B. The dummy channel layers 140D may be in contact with a dummy source/drain regions 150D. The dummy source/drain regions 150D may be disposed to be respectively adjacent to the third and fourth insulating separation patterns IP3 and IP4. The dummy source/drain regions 150D may be electrically insulated from each other by the third and fourth insulating separation patterns IP3 and IP4. The dummy source/drain regions 150D may include first and second dummy source/drain regions 150D adjacent to the third and fourth insulating separation patterns IP3 and IP4, respectively. The dummy channel layers 140D may be disposed in a region defined by the third and fourth insulating separation patterns IP3 and IP4, and the region may be an electrically insulated region. The lower pattern 195 may be disposed outside the area defined by the first and second insulating separation patterns IP1 and IP2. The first central portion CP may be disposed between the plurality of first extension portions EP1 and the second extension portions EP2, may serve to support a plurality of extension portions to mitigate or prevent the plurality of extension portions from collapsing, and may be connected to the rear, and may provide an aligned position in which each of the backside connection pattern 192 and a frontside connection pattern 250 is electrically connectable to the connection structure 170.

FIG. 5 is a plan view of a semiconductor device 100C according to an example embodiment of the present inventive concepts.

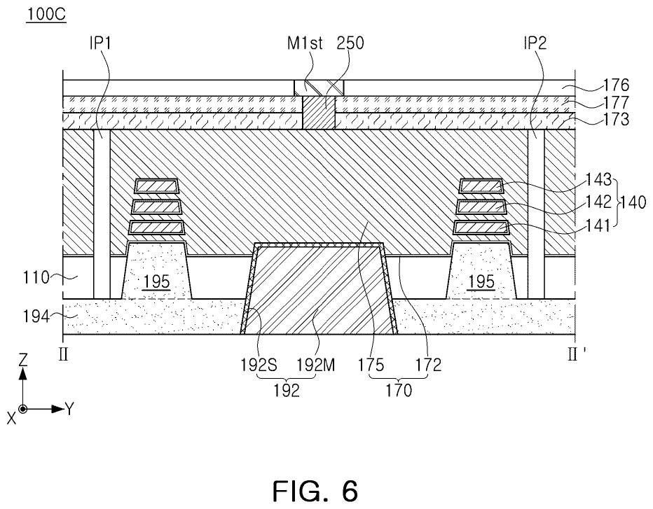

FIG. 6 is a cross-sectional view of the semiconductor device 100C in FIG. 5, taken along line II-II′.

Referring to FIGS. 5 and 6, the semiconductor device 100C according to an example embodiment may have features the same as or similar to those described with reference to FIGS. 1 to 4B, except that a connection structure 170 is disposed in a region in which a plurality of lower patterns 195 are defined by first and second insulating separation patterns IP1 and IP2. The first and second insulating separation patterns IP1 and IP2 may be disposed to be spaced apart from each other in a first direction (e.g., a Y-axis direction). Lower patterns 195 and a backside connection pattern 192 may be disposed between the first and second insulating separation patterns IP1 and IP2. A plurality of dummy channel layers may not be disposed in a region overlapping the backside connection pattern 192 in a vertical direction (e.g., a Z-axis direction), but the present inventive concepts are not limited thereto.

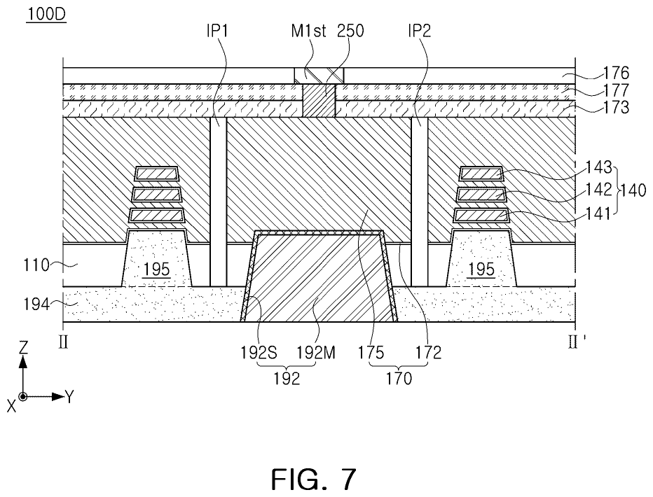

FIG. 7 is a cross-sectional view of a semiconductor device 100D according to an example embodiment of the present inventive concepts, taken along line II-II′.

Referring to FIG. 7, the semiconductor device 100D according to an example embodiment may have features the same as or similar to those described with reference to FIGS. 1 to 6, except that lower patterns 195 are disposed on the outside of a region defined by first and second insulating separation patterns IP1 and IP2, and dummy channel layers 140D (see FIG. 4B) overlapping a backside connection pattern 192 in a vertical direction is absent. The first and second insulating separation patterns IP1 and IP2 may be spaced apart from each other in a first direction (e.g., a Y-axis direction). The backside connection pattern 192 may be disposed in a region defined by the first and second insulating separation patterns IP1 and IP2, and the lower patterns 195 may be disposed on the outside of the region defined by the first and second insulating separation patterns IP1 and IP2. The lower patterns 195 may be spaced apart from the backside connection pattern 192 in the first direction. A plurality of channel layers may not be disposed in a region overlapping the backside connection pattern 192 in a vertical direction (e.g., Z-axis direction).

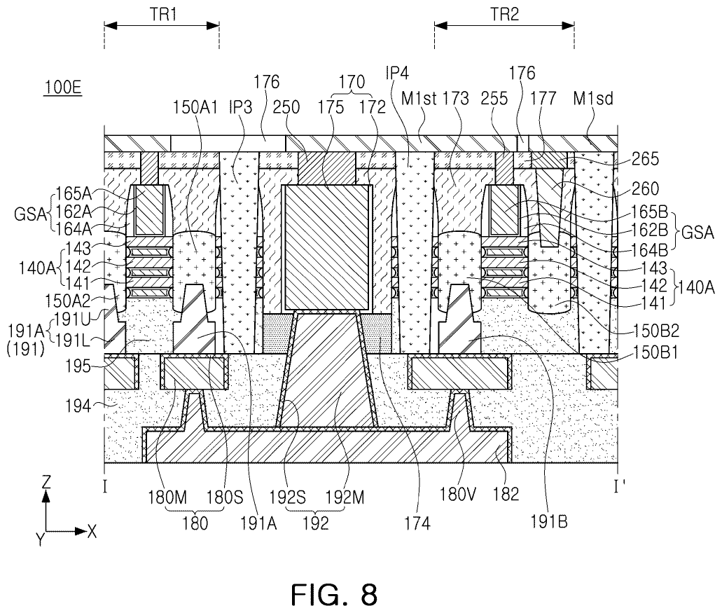

Semiconductor devices 100E, 100F, 100G, and 100H according to example embodiments of the present inventive concepts, illustrated in FIGS. 8 to 11, may have the same or similar features as those described with reference to FIGS. 1 to 7, except that there is a difference in levels on which a source/drain backside contact structure 191, a backside connection pattern 192, and a backside interconnection structure 180 are disposed.

FIG. 8 is a cross-sectional view of a semiconductor device 100E according to an example embodiment of the present inventive concepts, taken along line I-I′, and illustrates a region corresponding to that in FIG. 2A.

Referring to FIG. 8, the semiconductor device 100E according to an example embodiment may include a backside interconnection structure 180, a lower backside interconnection line 182 disposed below the first backside interconnection structure 180, and a backside interconnection via 180V disposed between the backside interconnection structures 180 and the lower backside interconnection line 182. The backside interconnection via 180V may electrically connect the backside interconnection structures 180 and the lower backside interconnection line 182 to each other. In an example embodiment, the backside interconnection via 180V may be integrated with the lower backside interconnection line 182. A backside connection pattern 192 may be electrically connected to a connection structure 170, and may be in contact with the lower backside interconnection line 182. A lower surface of the backside connection pattern 192 may be in contact with an upper surface of the lower backside interconnection line 182. The lower surface of the backside connection pattern 192 may be positioned on a level lower than that of a lower surface of the backside interconnection structure 180.

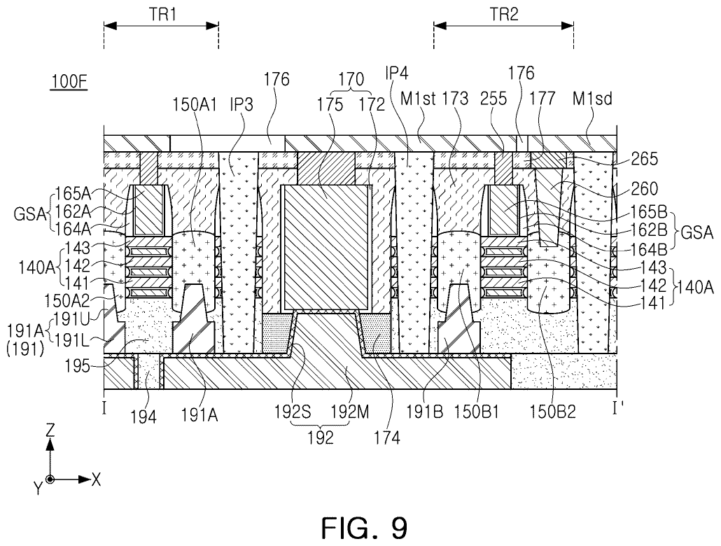

FIG. 9 is a cross-sectional view of a semiconductor device 100F according to an example embodiment of the present inventive concepts, taken along line I-I′, and illustrates a region corresponding to that in FIG. 2A.

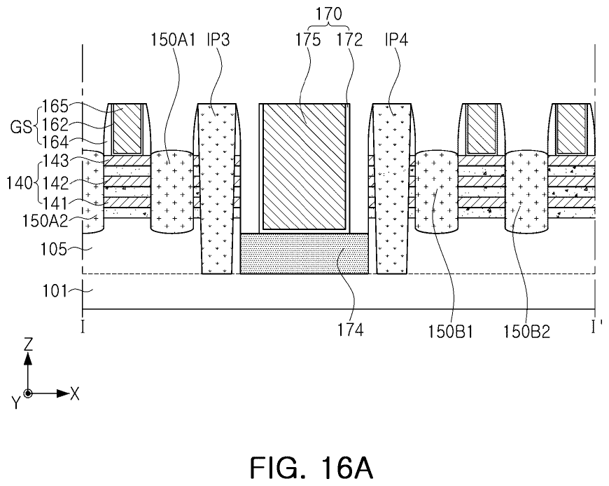

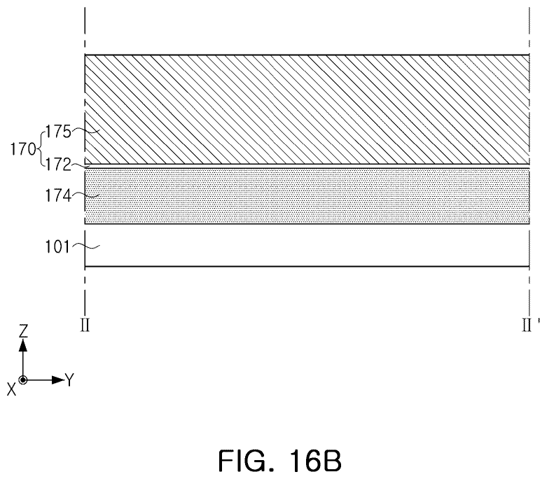

Referring to FIG. 9, the semiconductor device 100F according to an example embodiment may include a backside connection pattern 192 and a backside interconnection structure 180, integrated with each other. A backside contact barrier layer 192S may be formed to conformally cover a third recess region (“RS3” in FIGS. 16A and 16B). The backside contact barrier layer 192S may be in contact with a portion of a lower surface of a conductive connection pattern 175, and the backside contact barrier layer 192S may be in contact with a lower surface of a source/drain backside contact structure 191. A backside interconnection structure 180 and a backside contact conductive layer 192M may be formed on the backside contact barrier layer 192S, and may be formed using a single process.

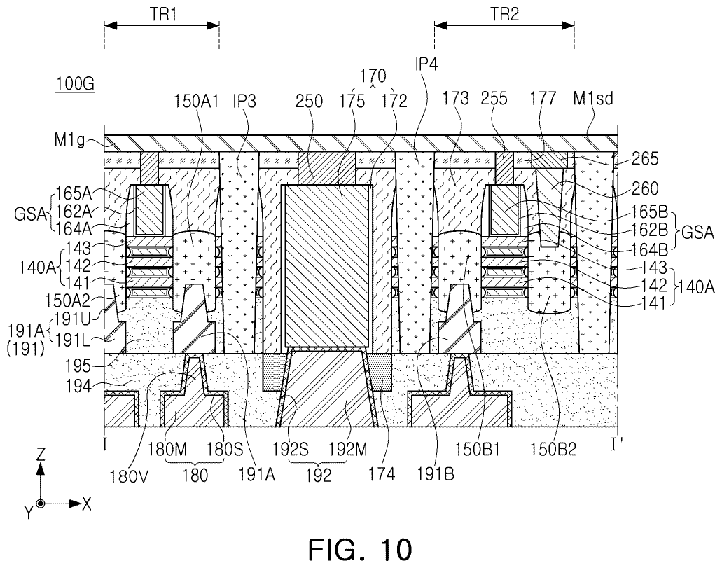

FIG. 10 is a cross-sectional view of a semiconductor device 100H according to an example embodiment of the present inventive concepts, taken along line I-I′, and FIG. 10 illustrates a region corresponding to that in FIG. 2A.

Referring to FIG. 10, the semiconductor device 100H according to an example embodiment may include a backside interconnection via 180V disposed between a backside interconnection structure 180 and a source/drain backside contact structure 191. The backside interconnection via 180V may have a cross-section having an width that gradually increases as a distance from the source/drain backside contact structure 191 increases. The backside interconnection via 180V may include a material the same as that of the backside interconnection structure 180. A backside connection pattern 192 may extend such that a lowermost end of the backside connection pattern 192 is positioned on a level the same as that of a lowermost end of the backside interconnection structure 180.

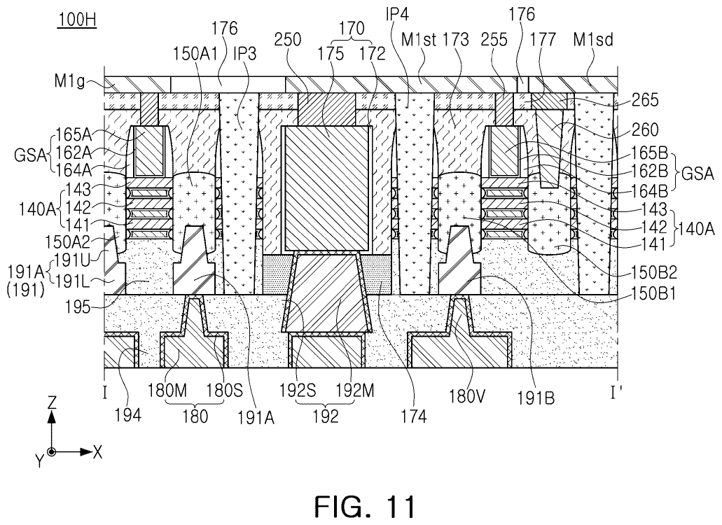

FIG. 11 is a cross-sectional view of a semiconductor device 100G according to an example embodiment of the present inventive concepts, taken along line I-I′, and FIG. 11 illustrates a region corresponding to that in FIG. 2A.

Referring to FIG. 11, the semiconductor device 100G according to an example embodiment may include a backside interconnection via 180V disposed between a backside interconnection structure 180 and a source/drain backside contact structure 191. The backside interconnection via 180V may have a cross-section having a width that gradually increases as a distance from the source/drain backside contact structure 191 increases. A backside connection pattern 192 may extend such that a lowermost end of the backside connection pattern 192 is positioned on a level the same as a lowermost end of a backside interconnection via 180V. A lowermost end of the backside interconnection structure 180 may be positioned on a level lower than the lowermost end of the backside connection pattern 192. An interconnection structure, which is positioned on a level the same as that of the backside interconnection structure 180, may be disposed below the backside connection pattern 192.

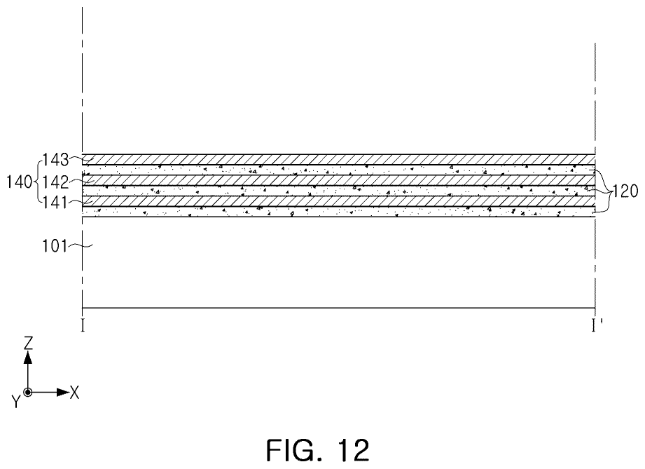

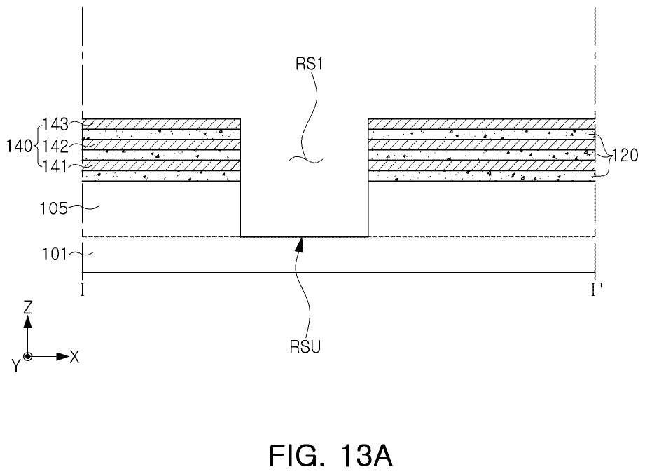

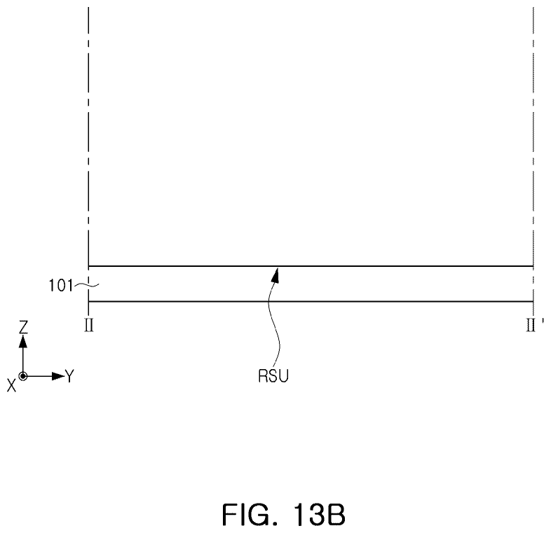

FIGS. 12 to 21B are cross-sectional views of sequential processes of a method of manufacturing the semiconductor device 100A according to an example embodiment of the present inventive concepts. FIGS. 12A to 21A are cross-sectional views corresponding to the manufacturing process in FIG. 2A illustrating a cross-section of the semiconductor device 100A in FIG. 1, taken along line I-I′, and FIGS. 13B to 21B are cross-sectional views corresponding to the manufacturing process in FIG. 2B illustrating a cross-section of the semiconductor device 100A in FIG. 1, taken along line II-II′.

Referring to FIG. 12, horizontal sacrificial layers 120 and channel layers 141, 142, and 143 may be alternately stacked on a semiconductor substrate 101.

The semiconductor substrate 101 may have an upper surface extending in an X-direction and a Y-direction. The semiconductor substrate 101 may include a semiconductor material, such as a group IV semiconductor, a group III-V compound semiconductor, or a group II-VI compound semiconductor. For example, the group IV semiconductor may include silicon, germanium, or silicon-germanium. The semiconductor substrate 101 may be provided as a bulk wafer, an epitaxial layer, a silicon on insulator (SOI) layer, or a semiconductor on insulator (SeOI) layer. The semiconductor substrate 101 may be removed using a subsequent process and then changed into a backside insulating layer 194 in the form of an insulating substrate filled with an insulating material.

As illustrated in FIG. 2A, the horizontal sacrificial layers 120 may be layers replaced with a first gate dielectric layer 162A and a gate electrode 165, below an uppermost channel layer 143, among a plurality of channel layers, using a subsequent process. The horizontal sacrificial layers 120 may be formed of a material having etch selectivity with respect to channel layers 141, 142, and 143, respectively. The channel layers 141, 142, and 143 may include a material different from that of the horizontal sacrificial layers 120. The horizontal sacrificial layers 120 and the channel layers 141, 142, and 143 may include, for example, a semiconductor material including at least one of silicon (Si), silicon germanium (SiGe), or germanium (Ge), may include different materials, and may or may not include impurities. For example, the horizontal sacrificial layers 120 may include silicon germanium (SiGe), and the channel layers 141, 142, and 143 may include silicon (Si).

The horizontal sacrificial layers 120 and the channel layers 141, 142, and 143 may be formed by performing an epitaxial growth process from the substrate 101. In example embodiments, the number of channel layers, stacked alternately with the horizontal sacrificial layers, may be changed in various manners.

Referring to FIGS. 13A and 13B, a semiconductor pattern 105 including active regions may be formed, and portions of the horizontal sacrificial layers 120 and the channel layers 141, 142, and 143 may be removed to form a first recess region RS1.

The semiconductor pattern 105, including active regions, may be formed on the semiconductor substrate 101. The semiconductor pattern 105 may extend in a first direction (e.g., an X-axis direction). The semiconductor pattern 105 may be defined to have a desired (or alternatively, predetermined) depth from an upper surface of a portion of the semiconductor substrate 101. The semiconductor pattern 105 may be formed as a portion of the semiconductor substrate 101, or may include an epitaxial layer grown from the semiconductor substrate 101. Each of the fin structures (e.g., semiconductor patterns) 105 may be in the form of an active fin upwardly protruding from an upper surface of the semiconductor substrate 101. The semiconductor pattern 105 may form an active structure in which a channel region of a transistor is formed, together with channel regions 140.

A device isolation layer 110 may be positioned between the semiconductor pattern 105, adjacent to each other in a second direction (e.g., a Y-axis direction). Upper surfaces of the semiconductor pattern 105 may be positioned on a level higher than that of an upper surface of the device isolation layer 110. The semiconductor pattern 105 may be formed by patterning the horizontal sacrificial layers 120, first to third channel layers 141, 142, and 143, and an upper region of the semiconductor substrate 101.

As illustrated in FIG. 1, the semiconductor pattern 105 may be in the form of a line extending in one direction, for example, the first direction (e.g., an X-axis direction), and may be spaced apart from each other in the second direction.

A portion of the semiconductor pattern 105 may be removed to form the first recess region RS1. In the first recess region RS1, an upper surface RSU of the semiconductor substrate 101 may be exposed. The first recess region RS1 may extend up to a level lower than that of a lowermost horizontal sacrificial layer, among the horizontal sacrificial layers 120. In an example embodiment, the first recess region RS1 may extend in a vertical direction up to a lower surface of the device isolation layer 110 on the semiconductor substrate 101, but the present inventive concepts is not limited thereto. The first recess region RS1 may extend in the second direction.

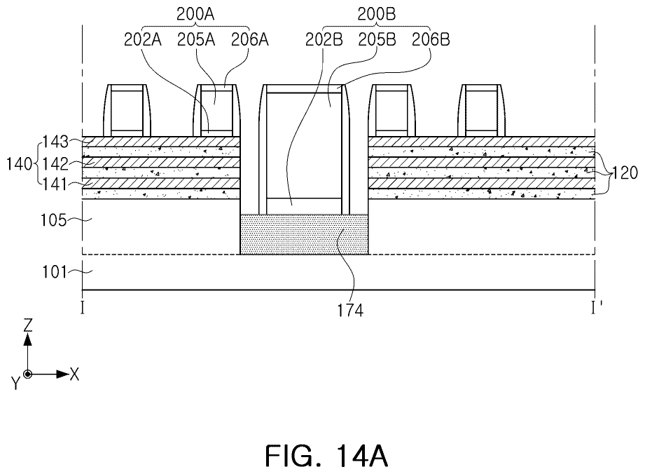

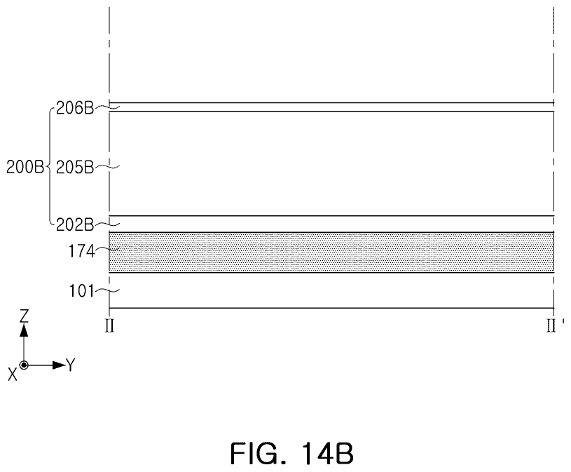

Referring to FIGS. 14A and 14B, in the first recess region RS1, an intermediate insulating layer 174 may be formed, and first sacrificial gate structures 200A and second sacrificial gate structures 200B may be formed.

The intermediate insulating layer 174 may be formed on the upper surface of the semiconductor substrate 101 (“RSU” in FIGS. 10A and 10B) in the first recess region RS1. The intermediate insulating layer 174 may include oxide, and may be formed to extend along the first recess region RS1 in the second direction (e.g., a Y-axis direction). In some example embodiments, the intermediate insulating layer 174 may be formed up to a level lower than that of a lower surface of a lowermost horizontal sacrificial layer, among the horizontal sacrificial layers 120, but the present inventive concepts are not limited thereto.

As illustrated in FIG. 2A, the first sacrificial gate structures 200A may be sacrificial structures formed using a subsequent process in a region in which a gate dielectric layer 162 and a gate electrode 165 are disposed on the channel regions 140. The first sacrificial gate structures 200A may have a line shape that intersects the lower pattern 105 and extends in the second direction.

The first sacrificial gate structure 200A may include first and second sacrificial gate layers 202A and 205A and a mask pattern layer 206A, sequentially stacked. The first and second sacrificial gate layers 202A and 205A may be patterned using the mask pattern layer 206A. The first and second sacrificial gate layers 202A and 205A may be an insulating layer and a conductive layer, respectively, but the present inventive concepts is not limited thereto, and the first and second sacrificial gate layers 202A and 205A may be formed as a single layer. For example, the first sacrificial gate layer 202A may include silicon oxide, and the second sacrificial gate layer 205A may include polysilicon. The mask pattern layer 206A may include silicon oxide and/or silicon nitride.

The second sacrificial gate structure 200B may have features the same as or similar to those of the first sacrificial gate structures 200A, and thus descriptions of the second sacrificial gate structure 200B may be partially replaced by the above descriptions of the first sacrificial gate structures 200A. The second sacrificial gate structure 200B may be formed on the intermediate insulating layer 174 to extend in the second direction. The second sacrificial gate structure 200B may be a dummy structure, changed into a connection structure 170 in a subsequent process, and a width of the second sacrificial gate structure 200B in the first direction may be wider than a width of the first sacrificial gate structure 200A in the first direction.

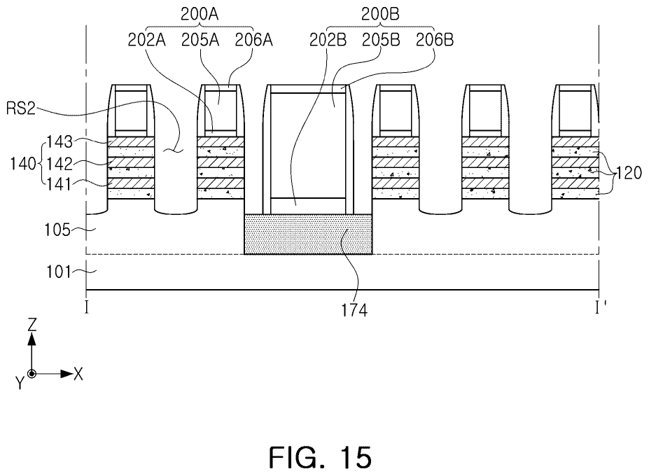

Referring to FIGS. 15A and 15B, portions of the exposed horizontal sacrificial layers 120 and first to third channel layers 141, 142, and 143 may be removed using the first sacrificial gate structures 200A as a mask to form second recess regions RS2.

The second recess regions RS2 may extend in a direction, perpendicular to an upper surface of the substrate 101, and a lowermost end of each of the second recess regions RS2 may be positioned on a level the same as that of an upper surface of the intermediate insulating layer 174, but the present inventive concepts is not limited thereto. In the present operation, the first to third channel layers 141, 142, and 143 may form the channel regions 140 having a limited length in the first direction (e.g., an X-axis direction). Subsequently, side surfaces of the horizontal sacrificial layers 120, exposed through the recess regions, may be partially removed to form internal spacer layers 130 in FIG. 2A.

Referring to FIGS. 16A and 16B, the first and second sacrificial gate structures 200A and 200B may be removed, and source/drain regions 150, gate structures GS, a connection structure 170, and third and fourth insulating separation patterns IP3, IP4 may be formed.

The source/drain regions 150 may be formed in the second recess regions RS2, and may be grown from side surfaces of the semiconductor pattern 105 and the channel regions 140 using, for example, a selective epitaxial process. The source/drain regions 150 may include impurities by in-situ doping, and may include a plurality of layers having different doping elements and/or doping concentrations. The source/drain regions 150 may be referred to differently depending on a position in which the source/drain regions 150 are formed.

The first sacrificial gate structures 200A may be removed to form gap regions (not illustrated), and then a first gate structure GSA, including a first gate dielectric layer 162A and a first gate electrode 165A filling the gap regions, may be formed. In the above process, a plurality of gate structures GS may be formed. In the removal and formation process, the source/drain regions 150 may be protected by the internal spacer layers 130.

A process of forming the connection structure 170 may have features the same as or similar to those of a process of forming the gate structures GS. The connection structure 170 may include an insulating liner 172 and a conductive connection pattern 175 formed on the insulating liner 172. The insulating liner 172 may be formed on the intermediate insulating layer 174 such that a lower surface thereof is in contact with an upper surface of the intermediate insulating layer 174.

Third and fourth insulating separation patterns IP3 and IP4 may be formed in a position of a first sacrificial gate structure adjacent to the second sacrificial gate structure 200B, among the first sacrificial gate structures 200A. The third and fourth insulating separation patterns IP3 and IP4 may include a material such as oxide, nitride, oxynitride, or combinations thereof, may extend up to a level the same as that of a lowermost end of the device isolation layer 110, and may pass through the semiconductor substrate 101, but the present inventive concepts are not limited thereto. The third and fourth insulating separation patterns IP3 and IP4 may extend up to a level the same as that of the lower surface of the intermediate insulating layer 174, but the present inventive concepts are not limited thereto.

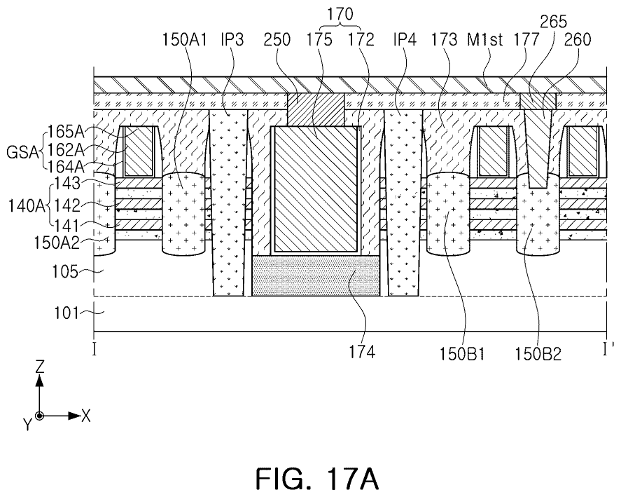

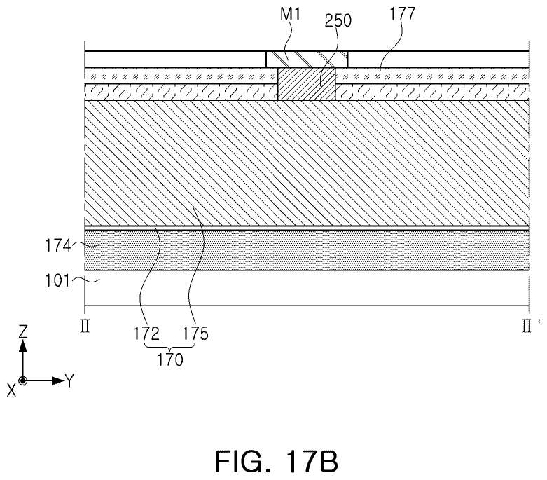

Referring to FIGS. 17A and 17B, a first interlayer insulating layer 173, a second interlayer insulating layer 177, and a frontside insulating layer 176 may be formed, and a first source/drain frontside contact plug 260 and a frontside connection pattern 250, a gate contact 255, and a first frontside interconnection structure M1 may be formed.

The first interlayer insulating layer 173 may cover at least a portion of each of the gate structures GS, the source/drain regions 150A and 150B, the intermediate insulating layer 174, and the connection structure 170. The first interlayer insulating layer 173 may be formed up to a level, higher than that of an upper surface of each of the connection structure 170 and the gate structures GS.

The first source/drain frontside contact plug 260, the frontside connection pattern 250, and a gate contact 255 may be formed to pass through at least a portion of the first interlayer insulating layer 173. A first source/drain frontside contact plug 260 may be formed to pass through at least a portion of one source/drain region 150B. A first source/drain frontside contact plug 260 may have a tapered shape having a width that gradually decreases toward the source/drain region 150B, but the present inventive concepts are not limited thereto. Each of a frontside connection pattern 250 and the gate contact 255 may be in contact with an upper surface of each of the connection structure 170 and the gate structure GS. An upper surface of each of the frontside connection pattern 250 and the gate contact 255 may be positioned on a level higher than that of an upper surface of the first source/drain frontside contact plug 260.

A first source/drain frontside contact via 265 may be disposed on the first source/drain frontside contact plug 260. An upper surface of the first source/drain frontside contact via 265 may be positioned on a level the same as that of the upper surface of each of the frontside connection pattern 250 and the gate contact 255. The first source/drain frontside contact via 265 may be surrounded by a second interlayer insulating layer 177 disposed on the same level. The first source/drain frontside contact via 265 may include a material the same as that of the first source/drain frontside contact plug 260, but the present inventive concepts are not limited thereto. Each of the first source/drain frontside contact via 265, the frontside connection pattern 250, and the gate contact 255 may be in contact with the first frontside interconnection structure M1 disposed on an upper portion thereof, and may be electrically connected to the first frontside interconnection structure M. The first frontside interconnection structure M1 may include a plurality of divided portions. The first frontside interconnection structure M1 is illustrated as a single layer, but the present inventive concepts are not limited thereto, and the first frontside interconnection structure M1 may include a plurality of lines stacked in a vertical direction (e.g., a Z-axis direction). In an example embodiment, the plurality of interconnection lines may include twelve interconnection lines, but the number thereof is not limited thereto. The plurality of interconnection lines further include interconnection vias electrically connecting, to each other, interconnection lines disposed on adjacent levels, and may provide various connection paths for electrical signals of a semiconductor device.

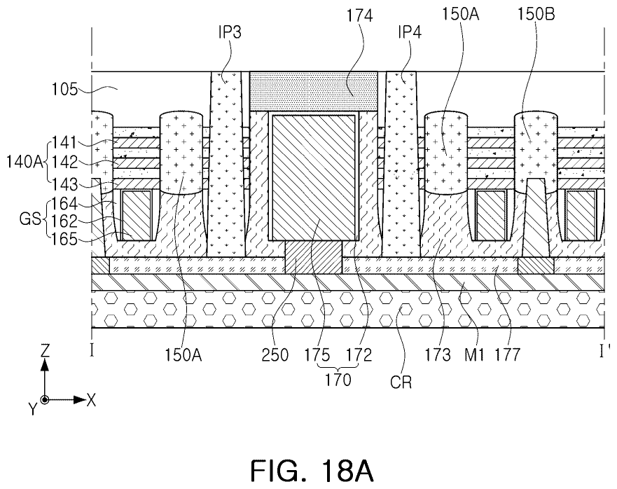

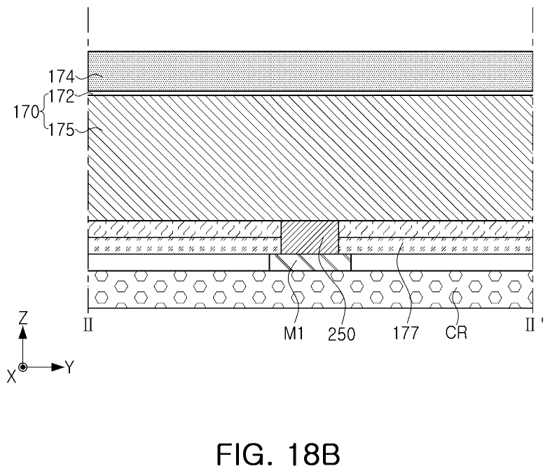

Referring to FIGS. 18A and 18B, the entire structure formed with reference to FIGS. 12A to 17B may be attached to a carrier substrate CR, a source/drain backside contact structure 191 may be formed, and the semiconductor substrate 101 may be removed.

The carrier substrate CR may be attached to the entire structure in order to perform a process on a lower surface of the semiconductor substrate 101 in FIGS. 17A and 17B. The carrier substrate CR may be in contact with the first frontside interconnection structure M1 and the frontside insulating layer 176 surrounding the first frontside interconnection structure M1. Specifically, the carrier substrate CR may be in contact with an uppermost insulating layer covering an uppermost interconnection line, among the plurality of interconnection lines of the first frontside interconnection structure M1. In the following drawings, to aid understanding, the entire structure is illustrated as being rotated or inverted in the form of a mirror image of the structure illustrated in FIGS. 17A and 17B.

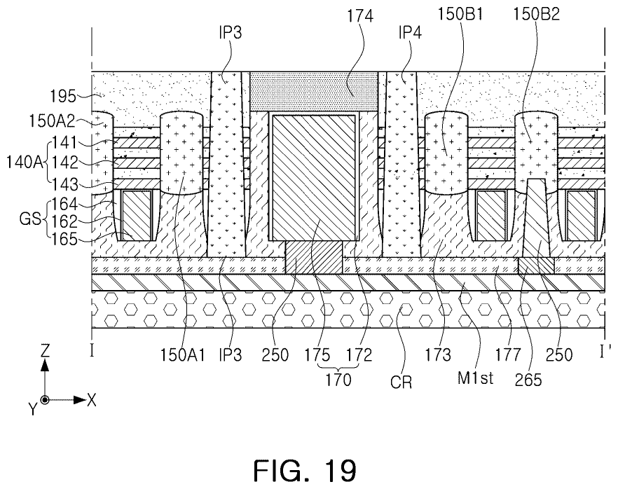

Referring to FIG. 19, the semiconductor pattern 105 (see FIGS. 18A and 18B) may be removed, and a lower pattern 195, covering at least a portion of each of the third and fourth insulating separation patterns IP3 and IP4 and the source/drain regions 150, may be removed. In an example embodiment, the lower pattern 195 may include an insulating material such as oxide or nitride to protect other conductive contact structures and source/drain regions, but the present inventive concepts are not limited thereto. The lower pattern 195 may be in contact with at least a portion of the source/drain regions 150. A lower surface of the lower pattern 195 may be positioned on a level the same as a lower surface of each of the third and fourth insulating separation patterns IP3 and IP4 and the intermediate insulating layer 174. Depending on example embodiments, at least a portion of the semiconductor pattern 105 may remain, and subsequent processes may be performed in a state in which at least a portion of the semiconductor pattern 105 remains.

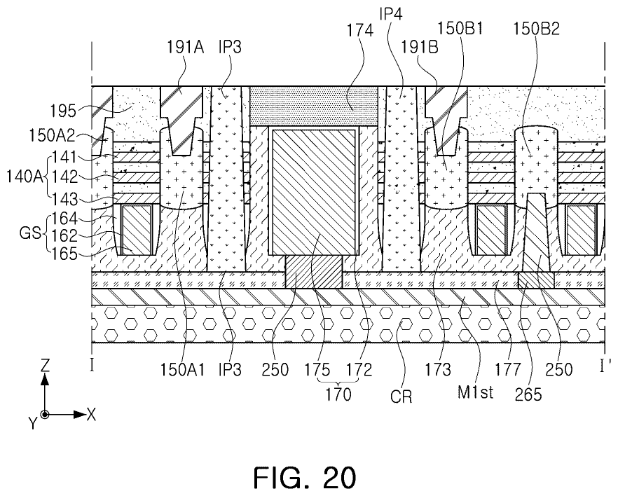

Referring to FIG. 20, the backside contact structures 191 may be formed to pass through at least a portion of the lower pattern 195, and to be connected to first to third source/drain regions 150A1, 150A2, and 150B1. The backside contact structures 191 may include an upper region 191U passing through at least a portion of the first to third source/drain regions 150A1, 150A2, and 150B1, and a lower region 191L extending from the upper region 191U.

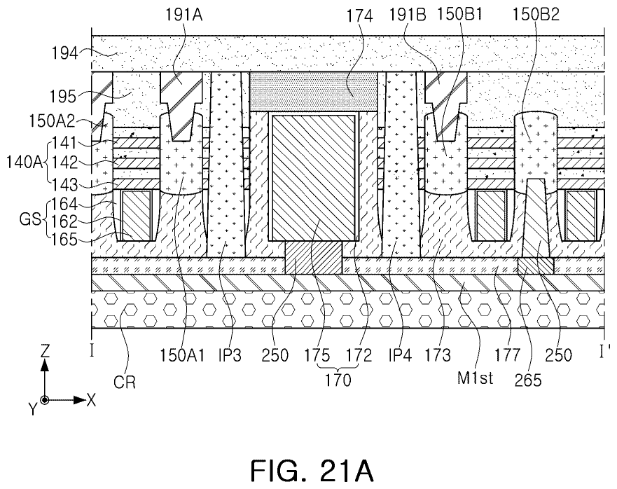

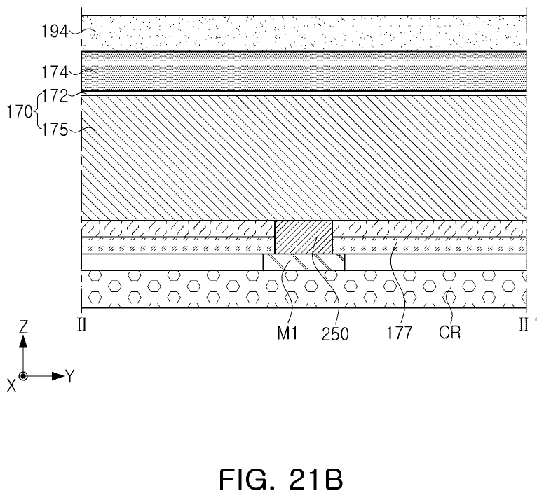

Referring to FIGS. 21A and 21B, a backside insulating layer 194 may be formed on the intermediate insulating layer 174 and the lower pattern 195. In an example embodiment, the backside insulating layer 194 may include a material the same as that of the lower pattern 195, but the present inventive concepts are not limited thereto, and may be formed as an insulating substrate including an insulating material such as oxide or nitride to protect other conductive contact structures, but the present inventive concepts are not limited thereto. The backside insulating layer 194 may extend in the first and second directions and may be formed to cover each of components of the entire structure attached to the carrier substrate CR. The backside insulating layer 194 may be disposed on the lower pattern 195. The lower surface of the lower pattern 195 and an upper surface of the backside insulating layer 194 may be positioned on the same level, and may correspond to an interface between the lower pattern 195 and the backside insulating layer 194.

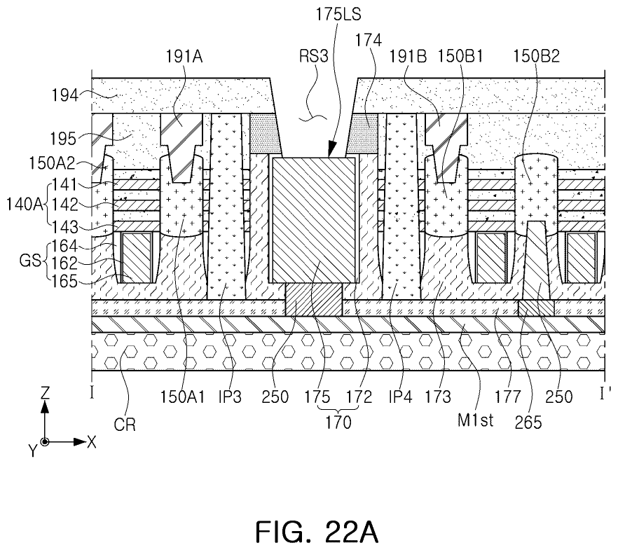

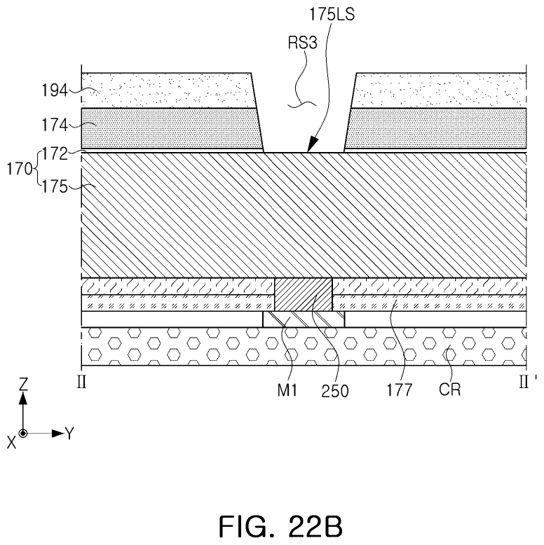

Referring to FIGS. 22A and 22B, a third recess region RS3 may be formed to expose at least a portion of a lower surface of the conductive connection pattern 175. Considering an aspect ratio of the third recess region RS3, the third recess region RS3 may have a cross-section having a width that gradually increases as a distance from the connection structure 170 increases. The third recess region RS3 may be formed by removing a portion of each of the backside insulating layer 194, the intermediate insulating layer 174, and the insulating liner 172. As a portion of the insulating liner 172 is removed, a portion of the conductive connection pattern 175 may be exposed from the insulating liner 172 in the third recess region RS3.

In such a process, a form or a level at which the third recess region RS3 is formed may be adjusted, thereby manufacturing the above-described semiconductor devices according to the example embodiments in FIGS. 5 to 8.

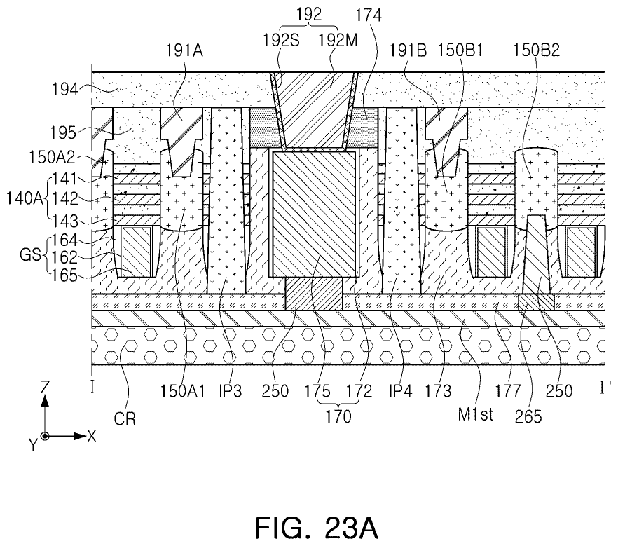

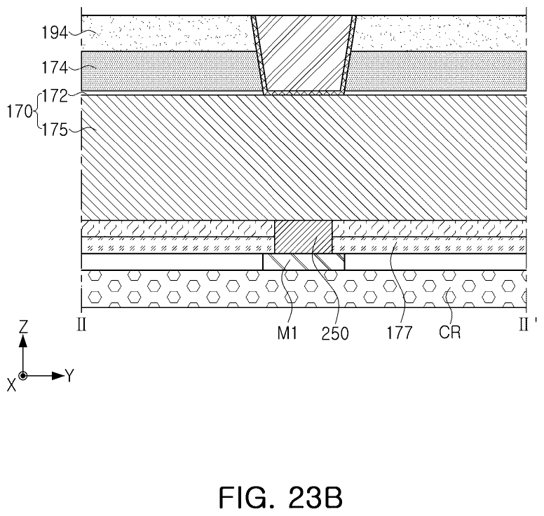

Referring to FIGS. 23A and 23B, a backside connection pattern 192 may be formed. A backside contact barrier layer 192S may be formed to conformally cover the third recess region (see “RS3” in FIGS. 22A and 22B). The backside contact barrier layer 192S may be a portion of a seed layer required for a plating process of the backside contact conductive layer 192M in a subsequent process. The backside contact barrier layer 192S may include a metal nitride, for example, titanium nitride (TiN), tantalum nitride (TaN), or tungsten nitride (WN). The backside contact conductive layer 192M may include a metal material such as copper (Cu), aluminum (Al), tungsten (W), or molybdenum (Mo). The backside contact barrier layer 192S and the backside contact conductive layer 192M may be subjected to a subsequent planarization process to form the backside connection pattern 192.

Subsequently, referring to FIGS. 1, 2A, and 2B together, the carrier substrate CR may be removed, and a backside interconnection structure 180, connected to the backside connection pattern 192, may be formed. Backside interconnection structures, including the backside interconnection structure 180, are illustrated as having a single-layer structure, but the present inventive concepts is not limited thereto, and may have a multilayer structure. Accordingly, the semiconductor device 100A in FIGS. 1 to 2B may be manufactured.

According to some example embodiments of the present inventive concepts, a connection structure and a contact structure electrically connected to a lower end of the connection structure may be used, thereby providing a semiconductor device having improved reliability and electrical properties.

While some example embodiments have been shown and described above, it will be apparent to those skilled in the art that modifications and variations could be made without departing from the scope of the present inventive concepts as defined by the appended claims.

What is claimed is:

1. A semiconductor device comprising:
a first transistor including a first gate electrode, a first gate dielectric layer, a first source/drain region, a second source/drain region, and a first channel region;
a second transistor being at a same level as the first transistor, the second transistor including a second gate electrode, a second gate dielectric layer, a third source/drain region, a fourth source/drain region, and a second channel region;
a first source/drain backside contact structure below the first source/drain region, the first source/drain backside contact structure connected to the first source/drain region;
a conductive connection pattern including at least a portion that is at a same level as the first and second gate electrodes;
a backside connection pattern below the conductive connection pattern, the backside connection pattern connected to the conductive connection pattern;
a frontside connection pattern on the conductive connection pattern, the frontside connection pattern connected to the conductive connection pattern;
a first frontside contact plug on the second transistor, the first frontside contact plug connected to the second transistor; and
a first frontside interconnection structure on the frontside connection pattern and the first frontside contact plug, the first frontside interconnection structure electrically connecting the frontside connection pattern and the first frontside contact plug to each other,
wherein the first channel region includes first channel layers spaced apart from each other in a vertical direction,
wherein the second channel region includes second channel layers spaced apart from each other in the vertical direction,
wherein the first channel layers are between the first source/drain region and the second source/drain region, and
wherein the second channel layers are between the third source/drain region and the fourth source/drain region.

2. The semiconductor device of claim 1, wherein
each of the first and second gate electrodes extends in a first direction, and
in a second direction perpendicular to the first direction, a maximum width of the conductive connection pattern is greater than a width of each of the first and second gate electrodes.

3. The semiconductor device of claim 1, wherein a distance between an upper surface and a lower surface of the conductive connection pattern is greater than a distance between an upper surface and a lower surface of the first gate electrode.

4. The semiconductor device of claim 1, wherein
the first gate electrode vertically overlaps the first channel layers, and
a lower surface of the first gate electrode is at a higher level than a lower surface of the conductive connection pattern.

5. The semiconductor device of claim 1, wherein
an upper surface of the conductive connection pattern is at a higher level than an uppermost first channel layer among the first channel layers, and
a lower surface of the conductive connection pattern is at a lower level than a lowermost first channel layer among the first channel layers.

6. The semiconductor device of claim 1, further comprising:
a first insulating separation pattern and a second insulating separation pattern,
wherein each of the first and second gate electrodes extends in a first direction,
the first and second insulating separation patterns are spaced apart from each other in the first direction, and
the conductive connection pattern is between the first and second insulating separation patterns.

7. The semiconductor device of claim 6, further comprising:
first external channel layers spaced apart from each other in the vertical direction; and
second external channel layers spaced apart from each other in the vertical direction,
wherein the first and second insulating separation patterns are between the first external channel layers and the second external channel layers.

8. The semiconductor device of claim 6, wherein the conductive connection pattern includes:
a first central portion;
first extension portions extending from the first central portion, the first extension portions being between the first central portion and the first insulating separation pattern; and
second extension portions extending from the first central portion, the second extension portions being between the first central portion and the second insulating separation pattern,
wherein the first extension portions are spaced apart from each other in a second direction perpendicular to the first direction, and
the second extension portions are spaced apart from each other in the second direction.

9. The semiconductor device of claim 6, further comprising:
a third insulating separation pattern between the first transistor and the conductive connection pattern; and
a fourth insulating separation pattern between the second transistor and the conductive connection pattern.

10. The semiconductor device of claim 9, wherein
an upper surface of each of the third and fourth insulating separation patterns are at a higher level than an upper surface of the conductive connection pattern,
a lower surface of each of the third and fourth insulating separation patterns are at a lower level than a lower surface of the conductive connection pattern.

11. The semiconductor device of claim 9, wherein
each of the first and second gate electrodes extends in the first direction,
each of the third and fourth insulating separation patterns extends in the first direction,
in a second direction perpendicular to the first direction, a maximum width of the conductive connection pattern is greater than a width of each of the third and fourth insulating separation patterns.

12. The semiconductor device of claim 9, wherein the conductive connection pattern is in contact with the first and second insulating separation patterns, and is spaced apart from the third and fourth insulating separation patterns.

13. The semiconductor device of claim 9, further comprising:
dummy channel layers being between the first and second insulating separation patterns, the dummy channel layers being between the third and fourth insulating separation patterns, the dummy channel layers spaced apart from each other in the vertical direction,
wherein the conductive connection pattern extends in the first direction and covers an upper surface, a lower surface, and a side surface of at least one of the dummy channel layers.

14. The semiconductor device of claim 13, wherein
a width of each of the dummy channel layers in a second direction is greater than a width of each of the first and second channel layers in the second direction, and
the second direction is perpendicular to the first direction.

15. The semiconductor device of claim 14, further comprising:
a first dummy source/drain region and a second dummy source/drain region,
wherein the dummy channel layers are between the first and second dummy source/drain regions, and
the first and second dummy source/drain regions are between the third and fourth insulating separation patterns.

16. The semiconductor device of claim 1, wherein
an upper surface of the first source/drain backside contact structure is at a higher level a lower surface of the conductive connection pattern, and
a lower surface of the first source/drain backside contact structure is at a lower level a lower surface of the conductive connection pattern.

17. The semiconductor device of claim 16, further comprising:
a first source/drain backside interconnection structure below the first source/drain backside contact structure, the first source/drain backside interconnection structure connected to the first source/drain backside contact structure,
wherein the lower surface of the first source/drain backside contact structure is at a higher level than a lower surface of the backside connection pattern.

18. The semiconductor device of claim 17, wherein a lower surface of the first source/drain backside interconnection structure is coplanar with a lower surface of the backside connection pattern.

19. A semiconductor device comprising:
a backside insulating layer;
a gate structure on the backside insulating layer, the gate structure including a gate electrode extending in a first direction;
a first source/drain region and a second source/drain region on opposite sides of the gate structure, the first source/drain region and the second source/drain region spaced apart from each other;
a channel region between the first and second source/drain regions, the channel region overlapping at least a portion of the gate electrode in a vertical direction;
a conductive connection pattern extending in the first direction, the conductive connection pattern including at least a portion that is at a same level as the gate electrode;
a frontside connection pattern on the conductive connection pattern, the frontside connection pattern being in contact with the conductive connection pattern;
a backside connection pattern below the conductive connection pattern, the backside connection pattern being in contact with the conductive connection pattern;
a first frontside contact plug on the gate electrode, the first frontside contact plug connected to the gate electrode;
a first frontside interconnection structure on the frontside connection pattern and the first frontside contact plug, the first frontside interconnection structure connecting the frontside connection pattern and the first frontside contact plug to each other;
a first backside contact structure below the first source/drain region, the first backside contact structure being connected to the first source/drain region; and
a first source/drain frontside contact plug on the second source/drain region, the first source/drain frontside contact plug connected to the second source/drain region.

20. The semiconductor device of claim 19, wherein
the channel region includes channel layers spaced apart from each other in a vertical direction, and
a lower surface of the backside connection pattern is at a lower level than a lower surface of the first backside contact structure.
